(19) United States
(12) Patent Application Publication
(10) Pub. No.: US 2025/0105820 A1
(43) Pub. Date: Mar. 27, 2025

(54) BRAGG STACK STRUCTURE FOR SPURIOUS MODE SUPPRESSION IN SOLIDLY-MOUNTED ACOUSTIC RESONATOR

(71) Applicant: Murata Manufacturing Co., Ltd., Nagaokakyo-shi (JP)

(72) Inventors: Bryant GARCIA, Mississauga (CA); Tetsuya Kimura, San Mateo, CA (US)

(21) Appl. No.: 18/889,894

(22) Filed: Sep. 19, 2024

Related U.S. Application Data
(60) Provisional application No. 63/585,053, filed on Sep. 25, 2023.

(51) Int. Cl. H03H 9/17; H03H 9/02; H03H 9/13; H03H 9/56

(52) U.S. Cl. CPC H03H 9/175; H03H 9/02031; H03H 9/02228; H03H 9/132; H03H 9/176; H03H 9/562; H03H 9/564; H03H 9/568

(57) ABSTRACT

An acoustic resonator device is provided that includes a substrate; a piezoelectric layer at least partially supported by the substrate; an interdigital transducer (IDT) at the piezoelectric layer; an acoustic Bragg reflector between the substrate and the piezoelectric layer. The acoustic Bragg reflector includes alternating layers of a first material and a second material having a higher acoustic impedance than the first material. Thicknesses of the first material and the second material of the acoustic Bragg reflector are configured to generate a reflectance frequency band centered around a displaced frequency f₀′, the displaced frequency f₀′ being displaced from a resonance frequency fᵣ of the acoustic resonator device based on a harmonic spur of the resonance frequency fᵣ. In this aspect, the thicknesses of the first material and the second material are measured in a direction normal to the substrate.

### CROSS REFERENCE TO RELATED APPLICATIONS

The present application claims priority to U.S. Patent Provisional Application No. 63/585,053, filed Sep. 25, 2023, the entire contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The Transversely-Excited Film Bulk Acoustic Resonator (XBAR) is an acoustic resonator structure for use in microwave filters. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

One type of XBAR is a Solidly Mounted XBAR (SM XBAR), which uses a Bragg stack or Bragg mirror to support a piezoelectric layer, instead of using a piezoelectric diaphragm. The Bragg stack is located between the substrate and the piezoelectric layer and includes alternating high-acoustic impedance and low-acoustic impedance layers, which define the reflectivity of the Bragg stack at various frequencies. That is, each Bragg stack has a corresponding frequency response, including a bandwidth over which reflection is good and stop-bands where reflection is poor (i.e., transmission is high).

Reflection and transmission in the context of the Bragg stack refer to reflection of energy moving down from the piezoelectric layer back toward the piezoelectric layer and transmission of energy moving from the piezoelectric layer down toward the substrate. The frequency response of each Bragg stack is the result of the materials and thickness of the high-acoustic impedance layers and the low-acoustic impedance layers of the Bragg stack.

That is, overall device performance of an SM XBAR is affected by the structure and frequency response of the Bragg stack, as these factors affect the energy reflected towards and transmitted away from the transducer structure of the SM XBAR. XBAR. The performance can be improved if the frequency response of the Bragg stack is optimized to maximize the energy/waves of the XBAR resonance mode that are reflected by the Bragg stack and to further maximize the energy/waves of spurious modes that are transmitted through the Bragg stack toward the substrate, away from the transducer structure of the XBAR.

### SUMMARY

Accordingly, SM XBAR performance would benefit from a Bragg stack structure that is optimized to maximize the energy/waves of the XBAR resonance mode that are reflected by the Bragg stack and maximize the energy/waves of spurious modes that are transmitted through the Bragg stack toward the substrate, away from the transducer structure of the XBAR.

Thus, in an exemplary embodiment, a bulk acoustic resonator device is provided that includes a substrate; a piezoelectric layer at least partially supported by the substrate; an interdigital transducer (IDT) on a surface of the piezoelectric layer, the IDT including interleaved fingers extending from first and second busbars, respectively; and an acoustic Bragg reflector between the substrate and the piezoelectric layer, the acoustic Bragg reflector comprising alternating layers of a first material and a second material having a higher acoustic impedance than the first material. Thicknesses of the first material and the second material of the acoustic Bragg reflector are configured to generate a reflectance frequency band centered around a displaced frequency f₀′, the displaced frequency f₀′ being displaced from a resonance frequency fᵣ of the bulk acoustic resonator device based on a harmonic spur of the resonance frequency fᵣ. Moreover, the thicknesses of the first material and the second material are measured in a direction substantially normal to the substrate.

In another exemplary aspect, the harmonic spur of the resonance frequency fᵣ comprises an A3 harmonic spur corresponding to 3fᵣ.

In another exemplary aspect, the displaced frequency f₀′ is higher than fᵣ.

In another exemplary aspect, the displaced frequency f₀′ is lower than fᵣ.

In another exemplary aspect, the thicknesses of the first material and the second material of the acoustic Bragg reflector are defined by:

$$\frac{{t}_{0 , m}^{′}}{{t}_{0}} \approx {( 1 \pm \frac{4}{m π} a sin ( \frac{1 - r}{1 + r} ) )}^{- 1} ,$$

wherein t₀ corresponds to a thickness of one of the first material or the second material that generates the reflectance frequency band centered around fᵣ, t_{0,m}′ corresponds to a thickness of one of the first material or the second material that generates the reflectance frequency band centered around the displaced frequency f₀′, m corresponds to an order of the harmonic spur, and r represents a ratio of an acoustic impedance of the first material to an acoustic impedance of the second material.

In another exemplary aspect, the thicknesses of the first material and the second material of the acoustic Bragg reflector are further defined by:

$$\frac{{t}_{0}^{′}}{{t}_{0}} = {( 1 \pm \frac{4}{3 π} a sin ( \frac{1 - r}{1 + r} ) \pm ϵ )}^{- 1} .$$

In this aspect, the harmonic spur is a third order harmonic spur and ϵ is an error component accounting for non-infinite steepness of the reflectance frequency band of the acoustic Bragg reflector and accounting for frequency positioning of the harmonic spur with respect to fᵣ.

In another exemplary aspect, m equals 3, such that the harmonic spur is a third order harmonic spur.

In another exemplary aspect of the bulk acoustic resonator device, wherein the reflectance frequency band of the Bragg reflector encompasses the resonance frequency fᵣ and an anti-resonance frequency fₐ of the bulk acoustic resonator device.

In another exemplary aspect of the bulk acoustic resonator device, the reflectance frequency band of the acoustic Bragg reflector is wider than a frequency band between the resonance frequency fᵣ and the anti-resonance frequency fₐ of the bulk acoustic resonator device.

In another exemplary aspect of the bulk acoustic resonator device, the first material and the second material are dielectric materials.

In another exemplary aspect of the bulk acoustic resonator device, each of the alternating layers of the acoustic Bragg reflector has a thickness in a range of 75% to 125% of one quarter of an acoustic wavelength corresponding to the displaced frequency f₀′, the acoustic wavelength propagating in the respective one of the alternating layers of the acoustic Bragg reflector.

Moreover, in an exemplary aspect of the bulk acoustic resonator device, the piezoelectric layer is one of a lithium niobate plate and a lithium tantalate plate.

In another exemplary aspect, the bulk acoustic resonator device further comprises at least one of a front side dielectric layer at a front side of the piezoelectric layer; or a back side dielectric layer at a back side of the piezoelectric layer.

In another exemplary aspect of the bulk acoustic resonator device, the piezoelectric layer and the IDT are configured to excite a bulk shear wave having a propagation direction perpendicular to a direction of a primarily laterally excited electric field generated by the IDT, the electric field being primarily laterally excited when atomic motion of the bulk shear wave is primarily horizontal in the piezoelectric layer, while the bulk shear wave propagates in a direction primarily perpendicular to the direction of atomic motion.

In yet another exemplary aspect, a filter device is provided that includes a plurality of bulk acoustic resonators. In this aspect, at least one of the plurality of bulk acoustic resonators includes a substrate; a piezoelectric layer at least partially supported by the substrate; an interdigital transducer (IDT) on a surface of the piezoelectric layer, the IDT including interleaved fingers extending from first and second busbars, respectively; and an acoustic Bragg reflector between the substrate and the piezoelectric layer, the acoustic Bragg reflector comprising alternating layers of a first material and a second material having a higher acoustic impedance than the first material. Moreover, thicknesses of the first material and the second material of the acoustic Bragg reflector are configured to generate a reflectance frequency band centered around a displaced frequency f₀′, the displaced frequency f₀′ being displaced from a resonance frequency fᵣ of the at least one of the plurality of bulk acoustic resonators based on a harmonic spur of the resonance frequency fᵣ. The thicknesses of the first material and the second material are measured in a direction substantially normal to the substrate.

In yet another exemplary aspect, a radio frequency module is provided that includes a filter device having a plurality of bulk acoustic wave resonators, one or more of the plurality of bulk acoustic wave resonators comprising an acoustic Bragg reflector between a substrate and a piezoelectric layer upon which interdigital transducers (IDTs) are configured to excite bulk acoustic waves in the piezoelectric layer; and a radio frequency circuit coupled to the filter device, the filter device and the radio frequency circuit being enclosed within a common package. In this aspect, the acoustic Bragg reflector comprises alternating layers of a first material and a second material having a higher acoustic impedance than the first material. Moreover, thicknesses of the first material and the second material of the acoustic Bragg reflector are configured to generate a reflectance frequency band centered around a displaced frequency f₀′, the displaced frequency f₀′ being displaced from a resonance frequency fᵣ of the one or more bulk acoustic wave resonators based on a harmonic spur of the resonance frequency fᵣ. The thicknesses of the first material and the second material are measured in a direction substantially normal to the substrate.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a graph showing a filter passband response and a mirror response of an SM XBAR according to an exemplary aspect.

FIG. 7 shows an exemplary graph of resonator admittance and Bragg reflectivity with respect to frequency values according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

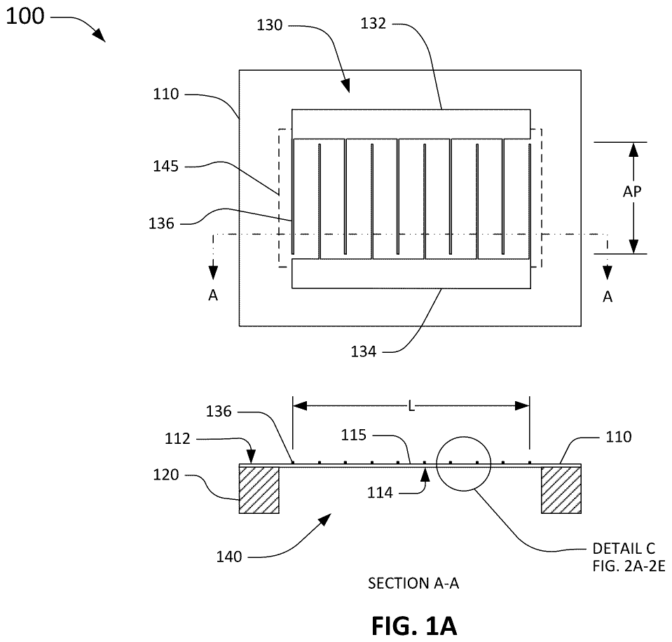

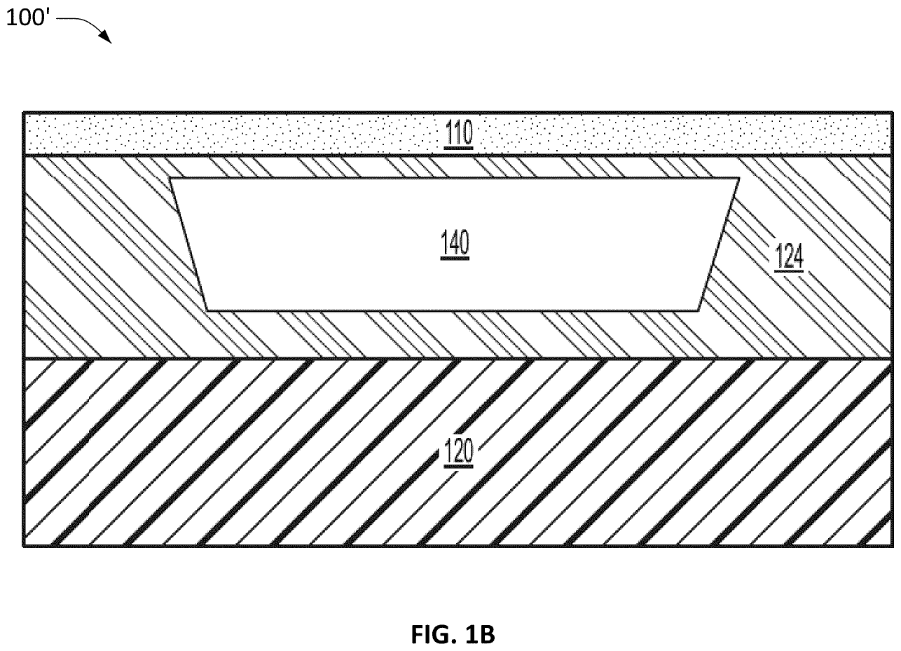

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

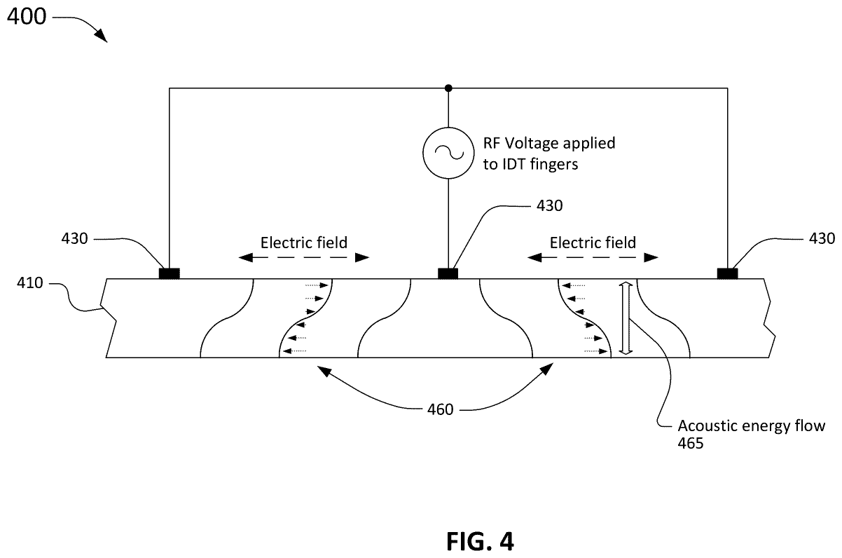

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

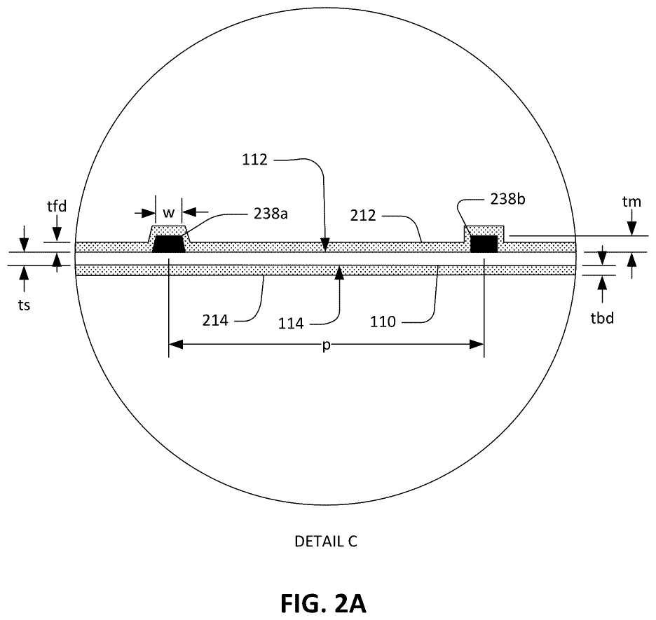

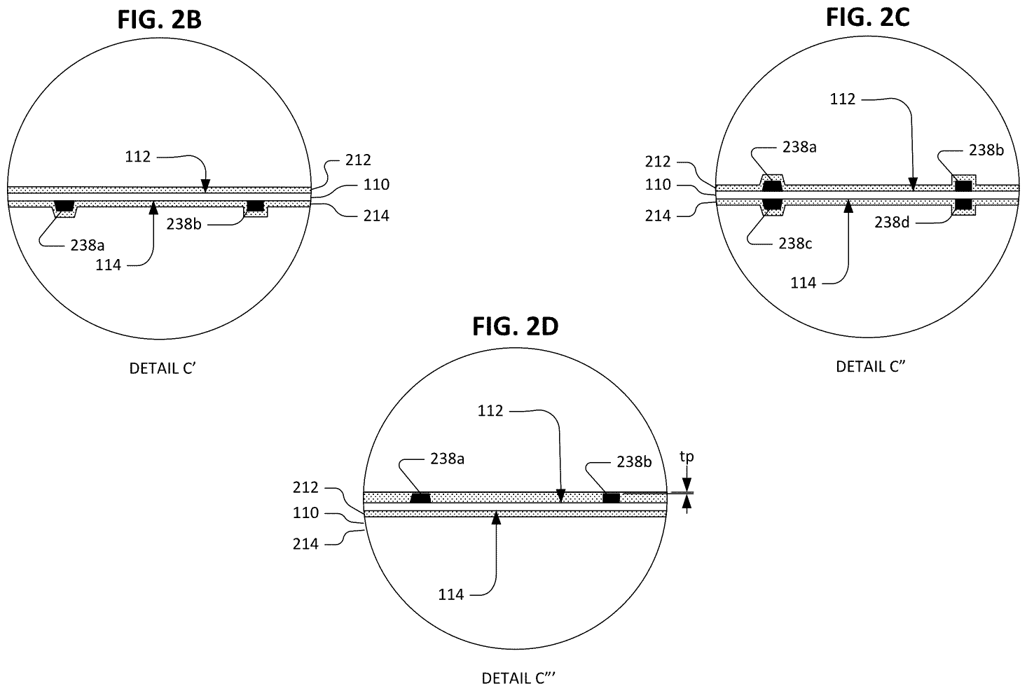

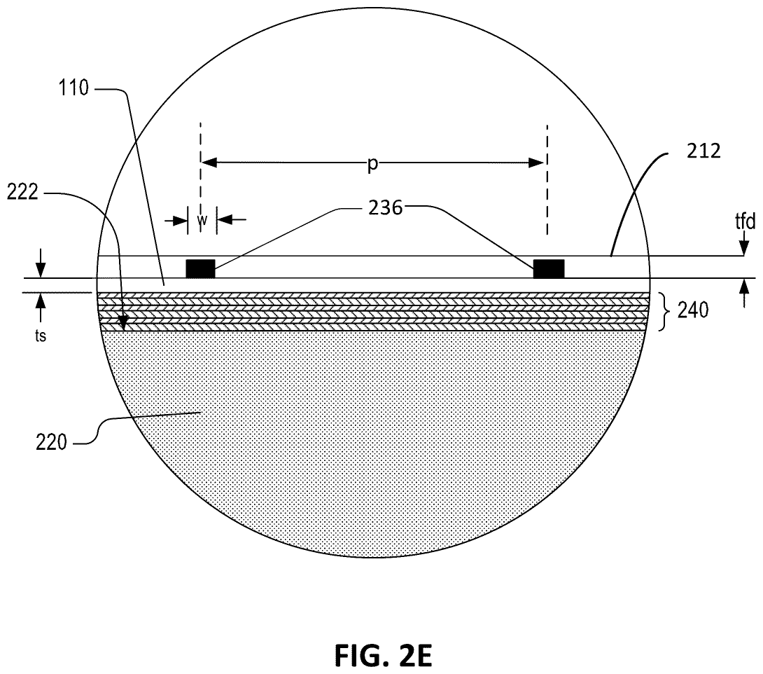

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers, in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. More generally, the acoustic Bragg reflector 240 includes alternating layers of a first material and a second material having a higher acoustic impedance than the first material. The acoustic impedance of each of the first and second materials is the product of the material's shear wave velocity and density. “High” and “low” are relative terms to each other. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

As will be discussed in detail below, according to the exemplar aspect, the thicknesses of the first material and the second material of the acoustic Bragg reflector (e.g., alternating low Z and high Z layers) are configured to generate a reflectance frequency band centered around a displaced frequency f₀′. The displaced frequency f₀′ is displaced from a resonance frequency fᵣ of the acoustic resonator device by a distance based on a harmonic spur of the resonance frequency fᵣ. Moreover, the thicknesses of the first material and the second material are generally measured in a direction normal to the substrate. Advantageously, this configuration maximizes the energy/waves of the XBAR resonance mode that are reflected by the Bragg stack and maximizes the energy/waves of spurious modes that are transmitted through the Bragg stack toward the substrate, away from the transducer structure of the XBAR.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer. Yet further, the IDT fingers may be disposed on the back side 114 of the piezoelectric layer 110 and embedded in one or more top layers of the Bragg reflector 240 and/or embedded in one or more intermediate (e.g., dielectric layers) between the Bragg reflector 240 and the piezoelectric layer 110.

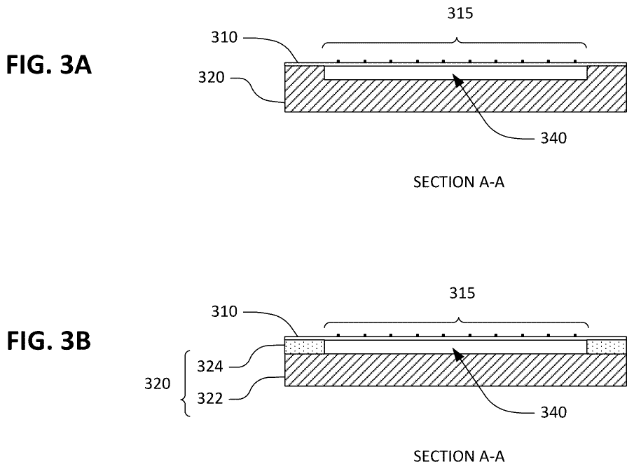

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. In this configuration, the piezoelectric layer and the IDT excite a bulk shear wave that has a propagation direction that is perpendicular to a direction of a primarily laterally excited electric field generated by the IDT. The electric field is primarily laterally excited when atomic motion of the bulk shear wave is primarily horizontal in the piezoelectric layer, while the bulk shear wave propagates in a direction primarily perpendicular to the direction of atomic motion.

Thus, as further shown, the shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

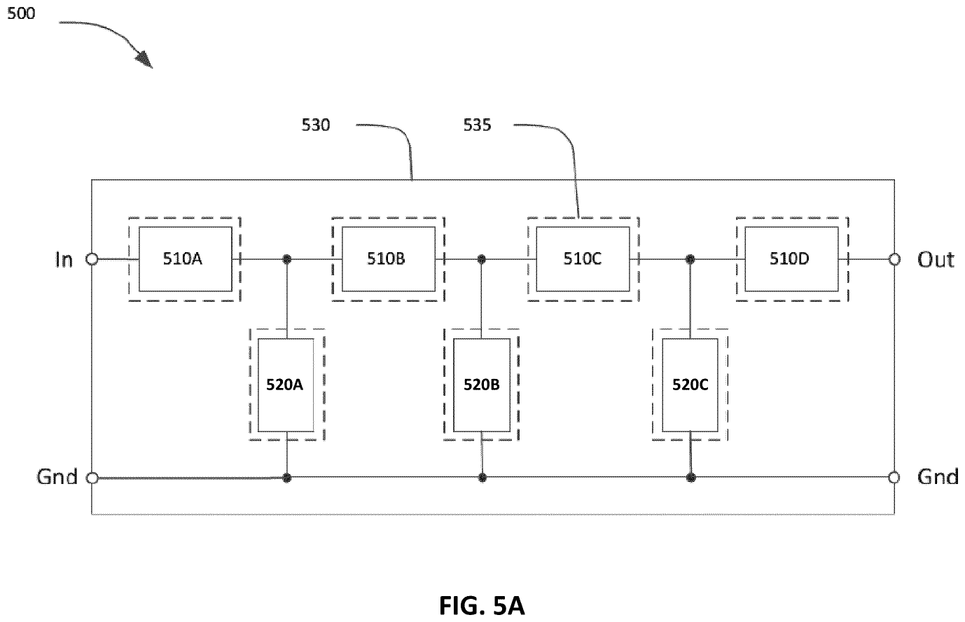

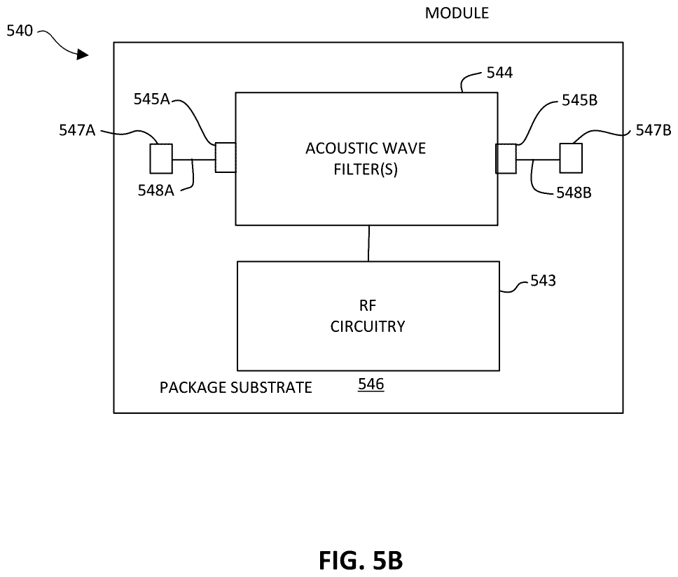

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over an acoustic mirror, such as the exemplary Bragg reflector structure described herein. That is, the alternating first and second materials of the Bragg reflector of one or more bulk acoustic wave resonators of the acoustic wave filter 544 can be configured to generate a reflectance frequency band centered around a displaced frequency f₀′ that is displaced from a center frequency f₀ of the acoustic wave filter 544 by a distance based on a harmonic spur of the acoustic wave filter 544.

Moreover, in this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (e.g., a radio frequency circuit/RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

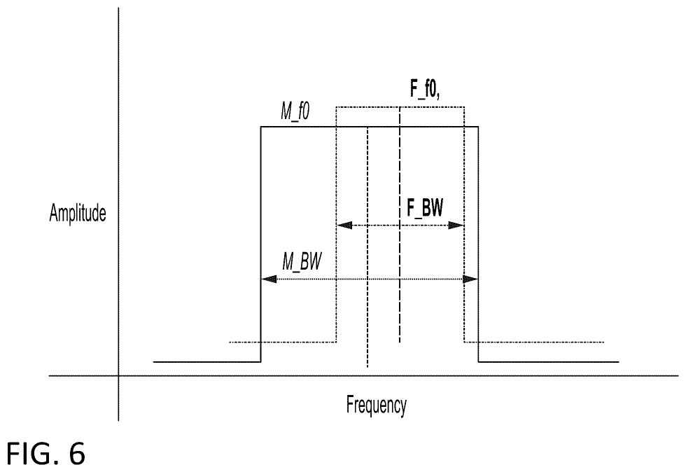

FIG. 6 shows a frequency response of a filter implemented using one or more SM XBARs, as well as the frequency response of Bragg stack(s) of the SM XBAR(s) according to an exemplary aspect. Generally, the frequency response of the Bragg stack does not have to be the same as the frequency response of the filter device in which the Bragg stack is used. However, if the frequency response of the Bragg stack is narrower than the filter bandwidth, performance of the filter will be compromised. On the other hand, having a frequency response of the Bragg stack that is wider than the filter bandwidth allows flexibility in designing the Bragg stack to suppress spurious modes of the filter device without affecting filter performance.

As described above, there is a relationship between the thicknesses of the layers of the Bragg stack and a center frequency of the frequency response of the Bragg stack, such that each layer of the acoustic Bragg stack has a thickness equal to, or about, one-fourth of the wavelength corresponding to the center frequency. Due to this relationship, the center frequency of the frequency response of the Bragg stack can be tuned by changing the thicknesses of the layers of the Bragg stack. It is noted (and also mentioned above) that the term “about” or “approximately” as used herein takes into account minor variations in dimensions, such as thicknesses, which may vary due to manufacturing variations and the like.

In an exemplary aspect, a generalized Bragg stack can be composed of alternating layers with respective acoustic impedances Z1 and Z2, and the thicknesses of the alternating layers can be set as

$$t = \frac{c}{4 {f}_{0}}$$

using the standard quarter-wavelength configuration, where c is the wave velocity in each respective layer and reflection is centered at frequency f₀. An infinite Bragg mirror of such alternating layers would then have a reflectance centered around f₀, with a fractional bandwidth given by

$$\frac{Δ f}{f} = \frac{4}{π} a sin ( \frac{1 - r}{1 + r} ) , r = \frac{{Z}_{1}}{{Z}_{2}} . \qquad ( Equation 1 )$$

The fractional bandwidth, Δf/f represents the ratio of the bandwidth of the Bragg stack to its center frequency. For example, in FIG. 6, Δf corresponds to the bandwidth (or reflectance frequency band) of the Bragg stack M_BW and the center frequency f corresponds to the center frequency M_f0 of the Bragg stack reflectance frequency band. While Equation 1 above represents the fractional bandwidth of an infinite Bragg mirror, a finite mirror or Bragg stack will have slightly different reflectance, depending on design and manufacturing precision.

Additionally, the ideal/infinite Bragg stack will have harmonic passbands for odd harmonics represented as f=mf₀, where m is odd. The harmonic passbands will have identical bandwidth Δf, but a lower fractional bandwidth Δf/f due to the higher frequency f. As noted above, a finite or non-ideal Bragg stack may have harmonic passbands that are slightly different than the above-described harmonic passbands.

FIG. 6 shows an example of a filter frequency response and a Bragg stack frequency response according to an exemplary aspect. As noted above, M_BW represents the bandwidth of the Bragg stack frequency response and M_f0 (e.g., the vertical small, dashed line) represents the center frequency of the Bragg stack frequency response. Likewise, F_BW represents the bandwidth of the overall filter frequency response and F_f0 (e.g., the vertical large, dashed line) represents the center frequency of the filter passband. According to the exemplary aspect, the displaced frequency (e.g., frequency f₀′ as described herein) is higher than the resonance frequency fᵣ of the acoustic resonator in this example. In an alternative aspect, the displaced frequency (e.g., frequency f₀′) may be lower than the resonance frequency fᵣ. In the context of the overall filter frequency response shown in FIG. 6, the displaced frequency (e.g., frequency f₀′) may be displaced from the center frequency of the filter passband and may be higher than or lower than the center frequency of the filter passband (e.g., F_f0 in FIG. 6). Moreover, in an exemplary aspect, the reflectance frequency band of the Bragg reflector can be configured to encompass the resonance frequency fᵣ and the anti-resonance frequency fₐ of an acoustic resonator device. In this aspect, the reflectance frequency band of the Bragg reflector may be wider than a frequency band between the resonance frequency fᵣ and the anti-resonance frequency fₐ of the acoustic resonator device.

In any such case according to the exemplary aspect as illustrated the FIG. 6, the center frequencies of the filter and Bragg stack are offset from each other, and the bandwidth of the Bragg stack is wider than the bandwidth of the filter. According to aspects of the present disclosure, the filter response is preserved as long as the Bragg stack bandwidth entirely contains the filter passband.

The condition of the Bragg stack bandwidth encompassing the filter passband may be described by the inequalities

$${M}_{f 0} - \frac{1}{2} {M}_{B W} < {F}_{f 0} - \frac{1}{2} {F}_{B W} \& {M}_{f 0} + \frac{1}{2} {M}_{B W} > {F}_{f 0} + \frac{1}{2} {F}_{B W} .$$

By combining these conditions and Equation 1 described above with respect to the fractional bandwidth of a Bragg mirror, the frequency response of a Bragg stack may be tuned according to the following bounds:

$${f}_{H} - \frac{2}{π} a sin ( \frac{1 - r}{1 + r} ) < {M}_{f 0} < {f}_{L} + \frac{2}{π} a sin ( \frac{1 - r}{1 + r} ) . \qquad ( Equation 2 )$$

In Equation 2, the variables f_{H} and f_{L} represent the high and low bounds (e.g., the upper and lower band edge frequencies) of the filter passband, M_{f0} is the center frequency of the Bragg stack frequency response, and r is the ratio of the respective acoustic impedances Z1 and Z2 of the Bragg stack. According to aspects of the present disclosure, following the bound conditions outlined by Equation 2 in designing the Bragg stack frequency response ensures that the main mode filter passband is preserved.

In terms of thickness, Equation 2 can be modified and represented as Equation 3 as follows:

$${f}_{H} - \frac{2}{π} a sin ( \frac{1 - r}{1 + r} ) < {c}_{z} / 4 {t}_{z} < {f}_{L} + \frac{2}{π} a sin ( \frac{1 - r}{1 + r} ) \qquad ( Equation 3 )$$

In this aspect for Equation 3, the center frequency of the Bragg reflector for a quarter wave is defined by Mf0=c/4t, where c is the speed of sound, t is the thickness of the particular impedance layer, and Z can indicate either high Z or low Z materials.

The description of FIG. 6 so far has indicated that the center frequency of the Bragg stack frequency response may be offset from the center frequency of the filter passband. Additionally, Equation 2 above defines the bounds within which the center frequency of the Bragg stack frequency response may be adjusted. Based on these constraints, the center frequency of the Bragg stack frequency response may be adjusted to suppress spurious modes of an XBAR device, for example, an A3 harmonic spur, according to an exemplary aspect.

The location of the A3 harmonic spur of XBAR devices may be approximated by f_{A3}≈3fᵣ, where fᵣ is the resonance frequency of the main XBAR mode. That is, the A3 harmonic spur corresponds to a frequency position that is approximately three times the resonance frequency of the XBAR (i.e., “3fᵣ”). The spurious harmonic mode at the approximate frequency f_{A3} can be minimized by moving the center frequency of the Bragg frequency response from fᵣ to a new (or displaced) central Bragg stack frequency f₀′.

For example, the new central Bragg stack frequency f₀′ selected to minimize the spurious A3 harmonic mode may be defined such that

$${f}_{0}^{′} = {f}_{r} \pm {f}_{0} \frac{4}{3 π} a sin ( \frac{1 - r}{1 + r} ) \approx {f}_{0} ( 1 \pm \frac{4}{3 π} a sin ( \frac{1 - r}{1 + r} ) ) .$$

As described above, tuning of the frequency response of the Bragg stack is accomplished by changing thicknesses of the alternating layers of the Bragg stack. Accordingly, using Equation 4, the ratio of a new Bragg layer thickness to an original Bragg layer thickness may be expressed as

$$\frac{{t}_{0}^{′}}{{t}_{0}} = {( 1 \pm \frac{4}{3 π} a sin ( \frac{1 - r}{1 + r} ) )}^{- 1} . \qquad ( Equation 5 )$$

In Equation 5, f₀ and t₀ represent Bragg stack center frequency and layer thickness that were originally centered on the main resonance frequency of the XBAR. t₀′ represents a new (or displaced) thickness of a corresponding Bragg layer that is offset from the main resonance frequency of the XBAR in order to suppress the spurious A3 harmonic mode of the XBAR. While Equations 3 and 4 above are directed to the A3 harmonic spur, suppression of the A3 spur is used as an example. Other asymmetric spurious modes may be suppressed in the same way, by moving the center frequency of the Bragg frequency response while adhering to the constraints of Equation 2.

Additionally, an error component may be introduced into Equation 5 to account for the non-infinite steepness of the Bragg mirror reflectivity roll-off, as well as to account for the assumptions made in calculating Equation 5, such as fᵣ=f₀ and f_{A3}=3fᵣ, which are in practice approximations. That is, the error component may be used to compensate, among other things, for the error in approximating the frequency positioning of the harmonic spur with respect to fᵣ. With the added error component ϵ, Equation 5 is modified to:

$$\frac{{t}_{0}^{′}}{{t}_{0}} = {( 1 \pm \frac{4}{3 π} a sin ( \frac{1 - r}{1 + r} ) \pm ϵ )}^{- 1} .$$

In some exemplary aspects, error component € may be equal to approximately 0.005. In other exemplary aspects, ϵ may be qual to several percent of the ratio t₀′/t₀ of the new Bragg layer thickness to the original Bragg layer thickness. A precise value for the error component ϵ may be determined through simulation, for example finite element method (FEM) simulation.

While Equations 3 and 4 are directed to minimizing the A3 harmonic spur, the expressions thereof can be generalized to apply to suppressing the m^{th} harmonic. For example, the ratio of a new Bragg layer thickness to the original Bragg layer thickness may be expressed as

$$\frac{{t}_{0 , m}^{′}}{{t}_{0}} = {( 1 \pm \frac{4}{m π} a sin ( \frac{1 - r}{1 + r} ) )}^{- 1} , \qquad ( Equation 6 )$$

where m represents the order of the targeted harmonic. Thus, in an exemplary aspect, m can equal 3 as the harmonic spur can be a third order harmonic spur (i.e., the A3 harmonic spur otherwise observed in the A3 mode).

The above-noted considerations regarding error component ϵ are applicable to Equation 6 as well, such that the right-hand side of Equation 6 may be considered an approximation without the error component. Additionally, the approximation accuracy of the right-hand side of Equation 6 becomes lower as the frequency/order of the targeted harmonic increases. Accordingly, the error component ϵ will have a correspondingly higher uncertainty with larger values of m.

It should be appreciated that the ± operator in Equations 4 and 5 indicates that the thickness of the Bragg stack layers may be either increased or decreased to minimize the effects of spurious modes on SM XBAR performance. In an exemplary aspect, the determination to increase or decrease the thickness of a given Bragg stack layer may be made based on design and/or fabrication factors, such as actual material losses, fabrication tolerances, and the like. Additionally, depending on the resulting frequency response of the Bragg stack, it may be possible to simultaneously dampen multiple spurious modes by selecting addition or subtraction for the ± operator.

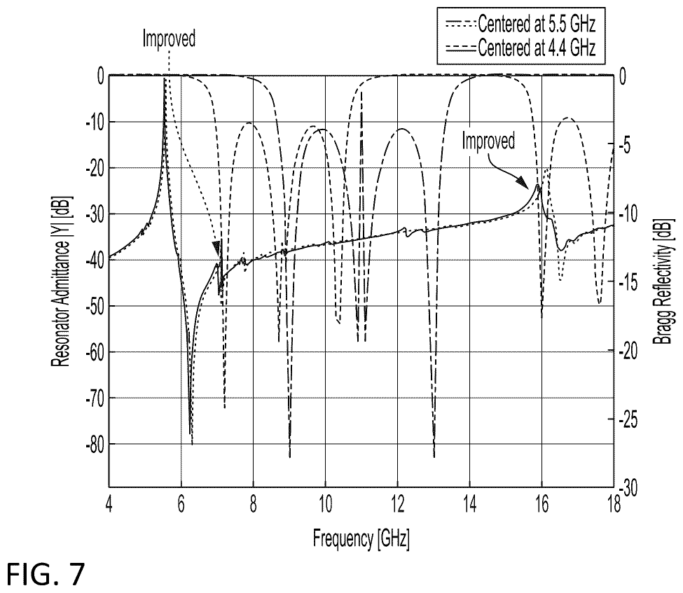

FIG. 7 shows an exemplary graph of resonator admittance and Bragg reflectivity with respect to frequency values according to an exemplary aspect. In FIG. 7, the solid curves represent resonator admittance, and the dashed curves represent Bragg reflectance. The plots shown in FIG. 7 are simulated using finite element method (FEM) simulation techniques. Additionally, the dotted and dash-shot-dash curves in FIG. 7 show simulation results when the frequency response of the Bragg stack is centered at 5.5 GHZ (i.e., approximately equal to the resonance frequency of the filter) and the solid and dashed curves show simulation results when the center frequency of the frequency response of the Bragg stack is shifted (or displaced) below the resonance frequency of the filter, to 4.4 GHz.

As indicated by the arrows in FIG. 7, the resonator admittance is improved in the solid curve, showing that shifting the center frequency of the frequency response of the Bragg stack dampens the spurious modes at 7 GHz and 16 GHz. This is evidenced by a lower spur at those frequencies in the solid curve, as compared to the dotted curve, which represents filter performance when the center frequency of the Bragg stack is approximately equal to the resonance frequency of the filter.

Generally, strategic shifting of the center frequency of the Bragg stack using, for example, Equations 4 or 5 described above, may be done to minimize out of band spurious modes, such as the spurs at 7 and 16 GHz in FIG. 7. Such out of band spurs affect the out-of-band rejection metrics of a filter. On the other hand, as long as the condition in Equation 2 is met, the strategic shifting of the Bragg stack center frequency to minimize out of band spurs will preserve in-band filter performance.

Using the example center frequencies (5.5 GHZ and 4.4 GHZ) of the Bragg stacks simulated in FIG. 7, Bragg stack layer thicknesses may be determined for each of the low acoustic impedance and high acoustic impedance layers of the Bragg stack. For example, for a center frequency of 5.5 GHZ, the low acoustic impedance (low Z) layer thickness may be 132 nm and the high acoustic impedance (high Z) layer thickness may be 105 nm. More generally, the thickness of the low acoustic impedance (low Z) layer may larger than the thickness of the high acoustic impedance (high Z) layer.

As another example, for a center frequency of 4.4 GHZ, the low Z layer thickness may be 165 nm and the high Z layer thickness may be 131 nm. The exemplary Bragg stack thickness values are based on the ratio of the acoustic impedance values of the low Z and high Z layers, as shown above in Equations 4 and 5.

In one example, each of the alternating low Z and high Z layers of the Bragg stack has a thickness in the range of 75% to 125% of one quarter the acoustic wavelength corresponding to the displaced frequency f₀′, where the acoustic wavelength is the wavelength propagating in the low Z and high Z layers, respectively. This configuration is shown in the shifting of the displace frequencies in the plot of FIG. 6 and minimizes out of band spurious modes in an exemplary configuration of the SM XBAR described herein. Additionally, the materials used for the low Z and high Z layers affect the Bragg stack layer thicknesses due to the original thickness quarter-frequency calculation of

$$t = \frac{c}{4 {f}_{0}} .$$

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bulk acoustic resonator device comprising:
a substrate;
a piezoelectric layer at least partially supported by the substrate;
an interdigital transducer (IDT) on a surface of the piezoelectric layer, the IDT including interleaved fingers extending from first and second busbars, respectively; and
an acoustic Bragg reflector between the substrate and the piezoelectric layer, the acoustic Bragg reflector comprising alternating layers of a first material and a second material having a higher acoustic impedance than the first material,
wherein thicknesses of the first material and the second material of the acoustic Bragg reflector are configured to generate a reflectance frequency band centered around a displaced frequency f₀′, the displaced frequency f₀′ being displaced from a resonance frequency fᵣ of the bulk acoustic resonator device based on a harmonic spur of the resonance frequency fᵣ, and
wherein the thicknesses of the first material and the second material are measured in a direction substantially normal to the substrate.

2. The bulk acoustic resonator device according to claim 1, wherein the harmonic spur of the resonance frequency fᵣ comprises an A3 harmonic spur corresponding to 3fᵣ.

3. The bulk acoustic resonator device according to claim 1, wherein the displaced frequency f₀′ is higher than fᵣ.

4. The bulk acoustic resonator device according to claim 1, wherein the displaced frequency f₀′ is lower than fᵣ.

5. The bulk acoustic resonator device according to claim 1, wherein the thicknesses of the first material and the second material of the acoustic Bragg reflector are defined by:
$$\frac{{t}_{0 , m}^{′}}{{t}_{0}} \approx {( 1 \pm \frac{4}{m π} a sin ( \frac{1 - r}{1 + r} ) )}^{- 1} ,$$
wherein t₀ corresponds to a thickness of one of the first material or the second material that generates the reflectance frequency band centered around fᵣ, t_{0,m}′ corresponds to a thickness of one of the first material or the second material that generates the reflectance frequency band centered around the displaced frequency f₀′, m corresponds to an order of the harmonic spur, and r represents a ratio of an acoustic impedance of the first material to an acoustic impedance of the second material.

6. The bulk acoustic resonator device according to claim 5, wherein the thicknesses of the first material and the second material of the acoustic Bragg reflector are further defined by:
$$\frac{{t}_{0}^{′}}{{t}_{0}} = {( 1 \pm \frac{4}{3 π} a sin ( \frac{1 - r}{1 + r} ) \pm ϵ )}^{- 1} ,$$
wherein the harmonic spur is a third order harmonic spur and ϵ is an error component accounting for non-infinite steepness of the reflectance frequency band of the acoustic Bragg reflector and accounting for frequency positioning of the harmonic spur with respect to fᵣ.

7. The bulk acoustic resonator device according to claim 5, wherein m equals 3, such that the harmonic spur is a third order harmonic spur.

8. The bulk acoustic resonator device according to claim 1, wherein the reflectance frequency band of the Bragg reflector encompasses the resonance frequency fᵣ and an anti-resonance frequency fₐ of the bulk acoustic resonator device.

9. The bulk acoustic resonator device according to claim 8, wherein the reflectance frequency band of the acoustic Bragg reflector is wider than a frequency band between the resonance frequency fᵣ and the anti-resonance frequency fₐ of the bulk acoustic resonator device.

10. The bulk acoustic resonator device according to claim 1, wherein the first material and the second material are dielectric materials.

11. The bulk acoustic resonator device of claim 1, wherein each of the alternating layers of the acoustic Bragg reflector has a thickness in a range of 75% to 125% of one quarter an acoustic wavelength corresponding to the displaced frequency f₀′, the acoustic wavelength propagating in the respective one of the alternating layers of the acoustic Bragg reflector.

12. The bulk acoustic resonator device of claim 1, wherein the piezoelectric layer is one of a lithium niobate plate and a lithium tantalate plate.

13. The bulk acoustic resonator device of claim 1, further comprising at least one of:
a front side dielectric layer at a front side of the piezoelectric layer; or
a back side dielectric layer at a back side of the piezoelectric layer.

14. The bulk acoustic resonator device of claim 1, wherein the piezoelectric layer and the IDT are configured to excite a bulk shear wave having a propagation direction perpendicular to a direction of a primarily laterally excited electric field generated by the IDT, the electric field being primarily laterally excited when atomic motion of the bulk shear wave is primarily horizontal in the piezoelectric layer, while the bulk shear wave propagates in a direction primarily perpendicular to the direction of atomic motion.

15. A filter device comprising:
a plurality of bulk acoustic resonators, at least one of the plurality of bulk acoustic resonators comprising:
a substrate;
a piezoelectric layer at least partially supported by the substrate;
an interdigital transducer (IDT) on a surface of the piezoelectric layer, the IDT including interleaved fingers extending from first and second busbars, respectively; and
an acoustic Bragg reflector between the substrate and the piezoelectric layer, the acoustic Bragg reflector comprising alternating layers of a first material and a second material having a higher acoustic impedance than the first material,
wherein thicknesses of the first material and the second material of the acoustic Bragg reflector are configured to generate a reflectance frequency band centered around a displaced frequency f₀′, the displaced frequency f₀′ being displaced from a resonance frequency fᵣ of the at least one of the plurality of bulk acoustic resonators based on a harmonic spur of the resonance frequency fᵣ, and
wherein the thicknesses of the first material and the second material are measured in a direction substantially normal to the substrate.

16. The filter device according to claim 15, wherein the harmonic spur of the filter device comprises an A3 harmonic spur.

17. The filter device according to claim 15, wherein the displaced frequency f₀′ is higher than f₀.

18. The filter device according to claim 15, wherein the displaced frequency f₀′ is lower than f₀.

19. The filter device according to claim 15, wherein the thicknesses of the first material and the second material of the acoustic Bragg reflector are defined by:
$$\frac{{t}_{0 , m}^{′}}{{t}_{0}} \approx {( 1 \pm \frac{4}{m π} a sin ( \frac{1 - r}{1 + r} ) )}^{- 1}$$
wherein t₀ corresponds to a thickness of one of the first material or the second material that generates a reflectance frequency band centered around fᵣ, t_{0,m}′ corresponds to a thickness of one of the first material or the second material that generates the reflectance frequency band centered around the displaced frequency f₀′, m corresponds to an order of the harmonic spur, and r represents a ratio of an acoustic impedance of the first material to an acoustic impedance of the second material.

20. A radio frequency module, comprising:
a filter device having a plurality of bulk acoustic wave resonators, one or more of the plurality of bulk acoustic wave resonators comprising an acoustic Bragg reflector between a substrate and a piezoelectric layer upon which interdigital transducers (IDTs) are configured to excite bulk acoustic waves in the piezoelectric layer; and
a radio frequency circuit coupled to the filter device, the filter device and the radio frequency circuit being enclosed within a common package,
wherein the acoustic Bragg reflector comprises alternating layers of a first material and a second material having a higher acoustic impedance than the first material,
wherein thicknesses of the first material and the second material of the acoustic Bragg reflector are configured to generate a reflectance frequency band centered around a displaced frequency f₀′, the displaced frequency f₀′ being displaced from a resonance frequency fᵣ of the one or more bulk acoustic wave resonators based on a harmonic spur of the resonance frequency fᵣ, and
wherein the thicknesses of the first material and the second material are measured in a direction substantially normal to the substrate.
